(19) United States
(12) Patent Application Publication
(10) Pub. No.: US 2007/0164668 A1
(43) Pub. Date: Jul. 19, 2007

(54) Organic electro-luminescent display

(76) Inventor: Hong Gyu Kim, Uiwang-si (KR)

Correspondence Address: KED & ASSOCIATES, LLP, P.O. Box 221200, Chantilly, VA, 20153-1200, US

(21) Appl. No.: 11/641,967

(22) Filed: Dec. 20, 2006

(30) Foreign Application Priority Data
Dec. 21, 2005 (KR) 10-2005-0127212

(51) Int. Cl. H01L 51/00

(52) U.S. Cl. 313/504

(57) ABSTRACT

An active matrix organic electro-luminescent (EL) display is disclosed. The organic electro-luminescent display includes an organic electro-luminescent device, a driving transistor, and a switching transistor, which are provided at each one of a plurality of pixel regions, a data line for applying a data signal to the switching transistor, a scan line for applying a scan signal to the switching transistor, and a common power supply line electrically connected to the driving transistors of neighboring ones of the pixel regions for applying a voltage to the driving transistors.

This application claims the benefit of the Korean Patent Application No. P2005-0127212, filed on Dec. 21, 2005, which is hereby incorporated by reference as if fully set forth herein.

### BACKGROUND OF THE INVENTION

1. Field of the Invention

The present invention relates to an organic electro-luminescent (EL) display, and more particularly, to an active matrix organic EL display.

2. Discussion of the Related Art

Generally, each pixel region of an organic EL display includes a switching thin-film transistor for switching a pixel corresponding to the pixel region, a driving thin-film transistor for driving the pixel, a storage capacitor, an anode (pixel electrode), an organic EL layer, and a cathode (common electrode).

Hereinafter, a method for manufacturing a conventional organic EL display will be described.

FIGS. 1A to 1C are sectional views illustrating a process for manufacturing a conventional organic EL display.

As shown in FIG. 1A, first, a semiconductor layer 2 made of, for example, polysilicon, is formed over a glass substrate 1. The semiconductor layer 2 is then patterned such that the semiconductor layer 2 remains only in a region where a thin film transistor is to be formed.

Thereafter, a gate insulating film 4 and a conductive film for formation of a gate electrode are sequentially formed over the entire surface of the resulting structure. The conductive film is then patterned to form a gate electrode 5.

Using the gate electrode 5 as a mask, impurity ions such as phosphorous (P) ions or boron (B) ions are then implanted into the semiconductor layer 2 which is, in turn, subjected to a heat treatment to form source and drain regions 3 of the thin film transistor.

Next, an interlayer insulating film 6 is formed over the entire surface of the resulting structure. Subsequently, the interlayer insulating film 6 and gate insulating film 4 are selectively removed such that the source and drain regions 3 of the thin film transistor are exposed.

Electrode lines 7 are then formed on the exposed source and drain regions 3 such that the electrode lines 7 are electrically connected to the source and drain regions 3, respectively.

Subsequently, a flattening insulating film 8 is formed over the entire surface of the resulting structure and selectively removed such that the specific electrode line 7 connected to the drain region is exposed.

Then, an anode 9 is formed on the exposed electrode line 7 such that the anode 9 is electrically connected to the electrode line 7.

Thereafter, as shown in FIG. 1B, an insulating film 10 is formed between neighboring anodes 9.

Next, a hole injection layer 11, a hole transfer layer 12, a light-emitting layer 13, an electron transfer layer 14, an electron implantation layer 15, and a cathode 16 are sequentially deposited over the entire surface of the resulting structure, to complete an organic EL device.

Then, as shown in FIG. 1C, a protective cap having a getter is disposed at an upper surface of the resulting organic EL device to encapsulate the organic EL device by use of a certain encapsulating material. Finally, if a polarizing plate is attached to a lower surface of the glass substrate by use of an adhesive, the manufacture of the organic EL display is completed.

However, the organic EL display manufactured by the above described method has a problem in that a red light emitting organic EL device, a blue light emitting organic EL device, and a green light emitting organic EL device have different electrical properties from one another.

Accordingly, as shown in FIG. 2, power has to be supplied to R, G, and B pixels individually.

For this reason, the conventional organic EL display exhibits a poor opening rate of pixels due to the design of the thin-film transistor. Furthermore, the conventional organic EL display suffers from an excessively increased number of external elements for supplying power to the respective R, G, and B pixels, resulting in significant deterioration of price competitiveness and element mounting ability.

### SUMMARY OF THE INVENTION

Accordingly, the present invention is directed to an organic electro-luminescent (EL) display that substantially obviates one or more problems due to limitations and disadvantages of the related art.

An object of the present invention is to provide an organic EL display in which a white light-emitting organic EL device is used and a power supply line for neighboring pixels is used as a common electrode, thereby achieving an improvement in the opening rate of pixels and considerably reducing the number of external elements used to drive the display while enabling a digital driving of the organic EL display.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an organic electro-luminescent display comprises: an electro-luminescent device including at least one of emitting layers for emitting white light; and a driving part for driving the electro-luminescent device, wherein the electro-luminescent device is operated by digital driving.

The driving part may be comprised a driving transistor for driving the organic electro-luminescent device; and a common power supply line for applying a voltage to the driving transistor, wherein the common power supply line is electrically connected to the driving transistors of neighboring ones of the pixel regions.

A voltage applied to the driving transistor is equal to or lower than 30 V.

The organic electro-luminescent device comprising an organic electro-luminescent device, a driving transistor, and a switching transistor, which are provided at each one of a plurality of pixel regions, further comprise: a data line for applying a data signal to the switching transistor; a scan line for applying a scan signal to the switching transistor; and a common power supply line electrically connected to the driving transistors of neighboring ones of the pixel regions for applying a voltage to the driving transistors.

organic electro-luminescent device may comprise: a first electrode electrically connected to the driving transistor; an organic electro-luminescent layer formed over the first electrode for emitting white light; and a second electrode formed over the organic electro-luminescent layer.

The organic electro-luminescent display may be operated by digital driving.

In accordance with another aspect of the present invention, there is provided an organic electro-luminescent display comprising: a transparent substrate having a plurality of pixel regions; first and second transistors formed at each pixel region of the transparent substrate; a first electrode formed at each pixel region and electrically connected to the first transistor; an organic electro-luminescent layer formed over the first electrode for emitting white light; a second electrode formed over the organic electro-luminescent layer; a data line electrically connected to the second transistor for applying a data signal to the second transistor; a scan line electrically connected to the second transistor for applying a scan signal to the second transistor; and a common power supply line electrically connected to the first transistors of neighboring ones of the pixel regions for applying a voltage to the first transistors.

A color filter layer is formed on at least one of a lower surface of the first electrode and an upper surface of the second electrode.

The second electrode may be grounded.

In accordance with a further aspect of the present invention, there is provided an organic electro-luminescent display comprising: a transparent substrate having a plurality of pixel regions; a thin-film transistor formed at each pixel region in a non light-emitting region of the pixel region; a color filter layer formed at each pixel region in a light-emitting region of the pixel region; an anode formed over the color filter layer and electrically connected to the thin film transistor; an organic electro-luminescent layer formed over the anode for emitting white light; a cathode formed over the organic electro-luminescent layer; and a common power supply line electrically connected to the thin-film transistors of neighboring ones of the pixel regions for applying a voltage to the thin-film transistors.

In accordance with yet another aspect of the present invention, there is provided an organic electro-luminescent display comprising: a transparent substrate having a plurality of pixel regions; a thin-film transistor formed at each pixel region in a non light-emitting region of the pixel region; an anode formed at each pixel region in a light-emitting region and electrically connected to the thin-film transistor; an organic electro-luminescent layer formed over the anode for emitting white light; a cathode formed over the organic electro-luminescent layer; a protective film formed over the cathode; a color filter layer formed over the protective film; a protective cap formed over the color filter layer; and a common power supply line electrically connected to the thin-film transistors of neighboring ones of the pixel regions for applying a voltage to the thin-film transistors.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1C are sectional views illustrating a process for manufacturing a conventional organic electro-luminescent display;

FIG. 2 is a circuit diagram illustrating the structure of pixels included in the conventional organic electro-luminescent display;

FIGS. 3A to 3C are sectional views illustrating a process for manufacturing an organic electro-luminescent display according to a first embodiment of the present invention; and

FIGS. 4A to 4D are sectional views illustrating a process for manufacturing an organic electro-luminescent display according to a second embodiment of the present invention; and

FIG. 5 is a circuit diagram illustrating the structure of pixels included in the organic electro-luminescent display according to the present invention.

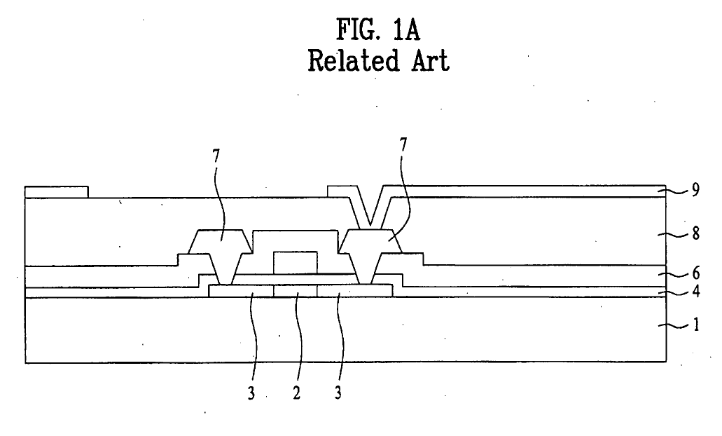

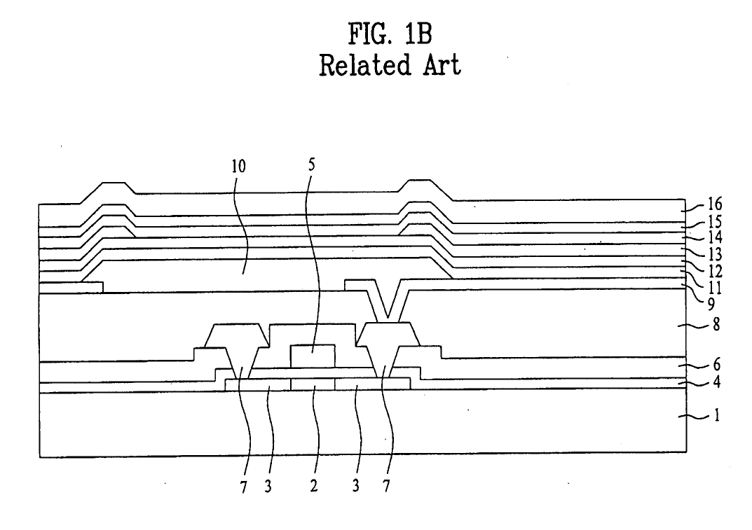

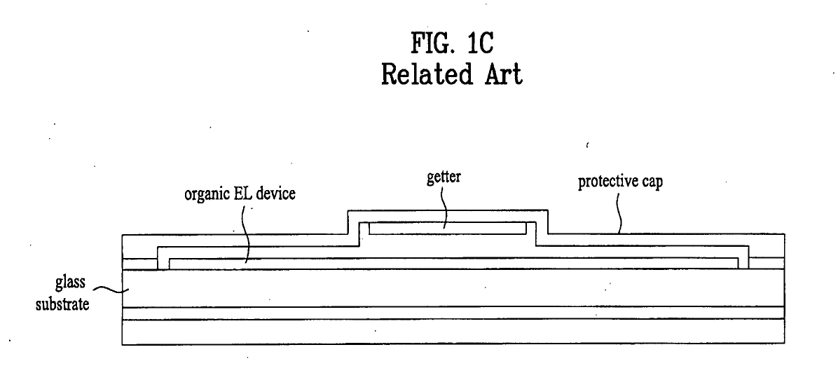

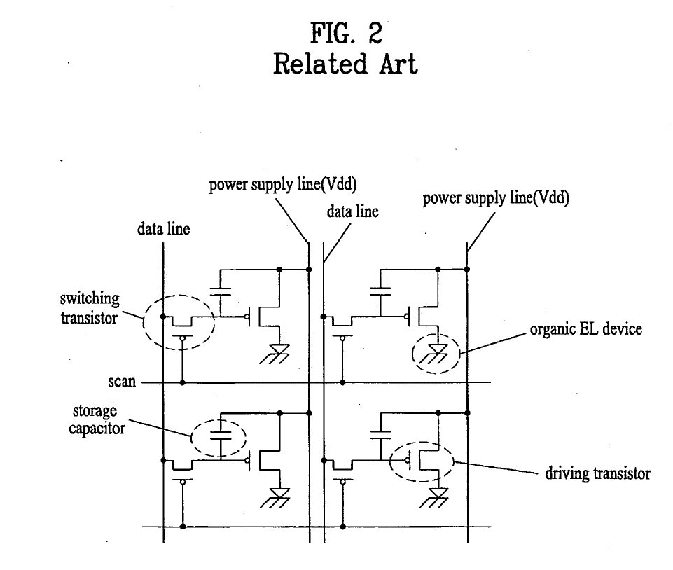

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

The present invention provides an organic electro-luminescent (EL) display characterized in that an organic EL layer for emitting white light and a color filter layer are simultaneously formed at a lower surface of an anode or at an upper surface of a cathode and a common power supply line is electrically connected to driving transistors of neighboring pixel regions so as to apply a voltage to the driving transistors and anode, thereby achieving an improvement in the opening ratio of pixels and simplifying the design of a drying circuit.

Each pixel region of the organic EL display according to the present invention includes an organic EL device, a driving transistor, and a switching transistor. The switching transistor is connected to a data line for applying a data signal to the switching transistor and a scan line for applying a scan signal to the switching transistor. The common power supply line is electrically connected to driving transistors of neighboring pixel regions, so as to apply a voltage to the driving transistors.

Here, the organic EL device may include a first electrode electrically connected to the driving transistor, the organic EL layer formed over the first electrode for emitting white light, and a second electrode formed over the organic EL layer.

A color filter layer may be formed on any one of a lower surface of the first electrode and an upper surface of the second electrode. The second electrode can be grounded.

The organic EL display of the present invention having the above described configuration can be driven in a digital manner.

In the present invention, the organic electro-luminescent display comprises an electro-luminescent device including at least one of emitting layers for emitting white light and a driving part for driving the electro-luminescent device.

Herein, the electro-luminescent device is operated by digital driving.

Also, the driving part may be comprised a driving transistor for driving the organic electro-luminescent device and a common power supply line for applying a voltage to the driving transistor.

Herein, the common power supply line is electrically connected to the driving transistors of neighboring ones of the pixel regions.

Also, it is desirable that a voltage applied to the driving transistor is equal to or lower than 30 V.

The electro-luminescent device of the present invention may be included at least one of a red emitting layer containing a phosphorescent material, blue emitting layer containing a phosphorescent material and green emitting layer containing a phosphorescent material.

Also, the organic electro-luminescent device of the present invention may be included at least one of a red emitting layer containing a phosphorescent material, blue emitting layer containing a fluorescent material and green emitting layer containing a phosphorescent material.

Also, the organic electro-luminescent device of the present invention may be included at least one of a red emitting layer containing a phosphorescent material, blue emitting layer containing a fluorescent material and green emitting layer containing a fluorescent material.

Herein, the phosphorescent material is selected from Iridium(111) (2-(3′-tolyl)-5-methylquinolinato-N,C^{2′})(2,4-pentanedionate-O,O), Iridium(111(2-(3-methylphenyl)-4,7-dimethylquinolinato-N,C^{2′})(2,4-pentanedionate-O,O), etc., and the fluorescent material is selected from 9-[4-(2,2-diphenyl-vinyl)-phenyl]-10-(4-trityl-phenyl)-antracene, N,N′-Di-naphthalen-2-yl-N,N′-di-p-tolyl-anthracene-9,10-diamine, etc.

Now, two basic digital driving methods for the organic EL display of the present invention will be described.

the first method, after recording data in entire pixels of a display panel, the entire pixels are simultaneously operated to emit light.

the second method, data is recorded in each pixel of a display panel and simultaneously, the pixel is operated to emit light.

The present invention employs the above described first method for emitting light from the entire pixels, and thus, the respective pixels have the same electrical property as one another.

Accordingly, according to the present invention, even if neighboring pixels commonly use a single power supply line to perform a digital driving, there is no adverse effect on the light emitting characteristics of the pixels. This is better to simplify the design of a driving circuit.

Hereinafter, a process for manufacturing the organic EL display according to the present invention having the above described characteristics will be described.

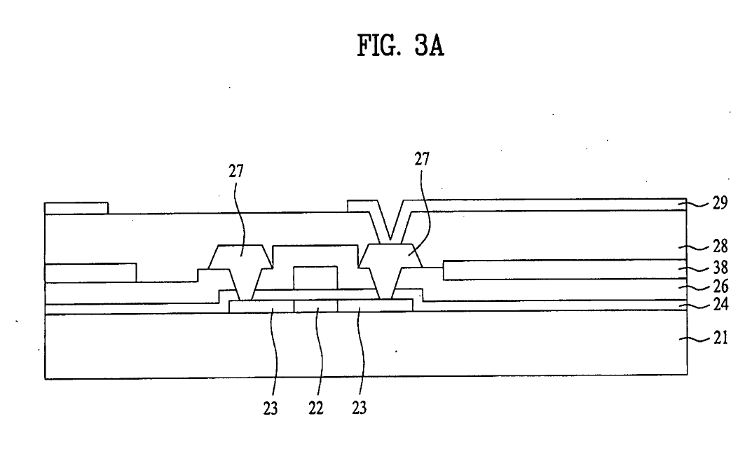

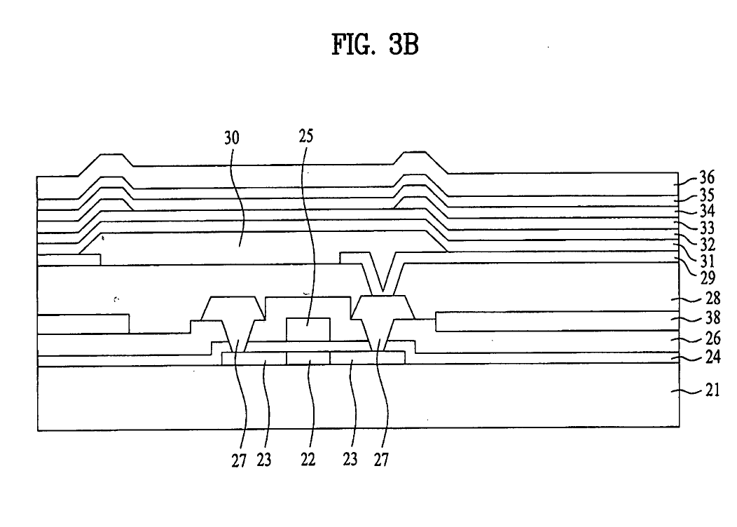

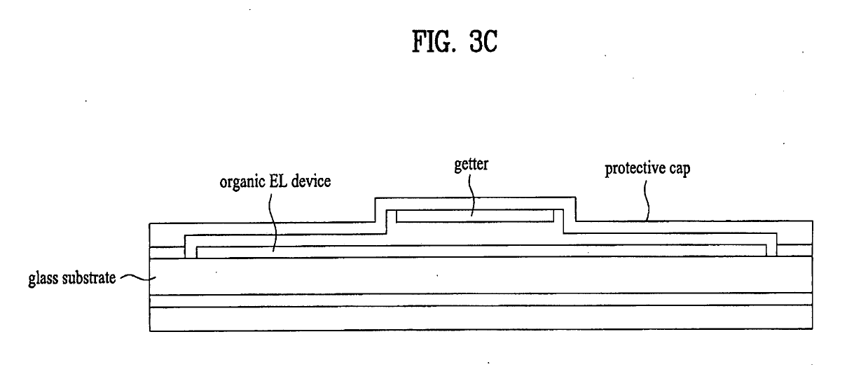

FIGS. 3A to 3C are sectional views illustrating a process for manufacturing an organic electro-luminescent display according to a first embodiment of the present invention.

The first embodiment of the present invention discloses a process for manufacturing a bottom emission type organic EL display.

Referring first to FIG. 3A, a semiconductor layer 22 made of, for example, polysilicon, is formed over a glass substrate 21. The semiconductor layer 22 is then patterned such that the semiconductor layer 22 remains only in a region where a thin film transistor is to be formed.

Thereafter, a gate insulating film 24 and a conductive film for formation of a gate electrode are sequentially formed over the entire surface of the resulting structure. The conductive film is then patterned to form a gate electrode 25.

Using the gate electrode 25 as a mask, impurity ions such as phosphorous (P) ions or boron (B) ions are then implanted into the semiconductor layer 22 which is, in turn, subjected to a heat treatment to form source and drain regions 23 of the thin film transistor.

Next, an interlayer insulating film 26 is formed over the entire surface of the resulting structure. Subsequently, the interlayer insulating film 26 and gate insulating film 24 are selectively removed such that the source and drain regions 23 of the thin film transistor are exposed.

Electrode lines 27 are then formed on the exposed source and drain regions 23 such that the electrode lines 27 are electrically connected to the source and drain regions 23, respectively.

Subsequently, an R, G, and B color filter layer 38 is formed to correspond to an R, G, and B pixel region where an anode is to be formed.

Then, a flattening insulating film 28 is formed over the entire surface of the resulting structure and selectively removed such that the specific electrode line 27 connected to the drain region is exposed.

Then, an anode 29 is formed on the exposed electrode line 27 such that the anode 29 is electrically connected to the electrode line 27.

Here, the anode 29 is made of a transparent conductive material having a high work function, such as ITO, IZO, etc.

Thereafter, as shown in FIG. 3B, an insulating film 30 is formed between neighboring anodes 29.

Next, a hole injection layer 31, a hole transfer layer 32, a light-emitting layer 33, an electron transfer layer 34, an electron implantation layer 35, and a cathode 36 are sequentially deposited over the entire surface of the resulting structure, to complete an organic EL device.

Here, the cathode 36 is made of a conductive material having a low work function, such as aluminum, etc.

Then, as shown in FIG. 3C, a protective cap having a getter is disposed over the resulting organic EL device to encapsulate the organic EL device by use of a certain encapsulating material. Finally, if a polarizing plate is attached to a lower surface of the glass substrate by use of an adhesive, the manufacture of the organic EL display is completed.

Here, although not shown, a power supply line for applying a voltage to the thin-film transistor is formed such that a common power supply line is electrically connected to the thin-film transistors of neighboring pixel regions.

The cathode 36 is a common electrode and can be grounded.

The above described organic EL display, which is manufactured by use of a white light emitting material, is driven in a digital manner.

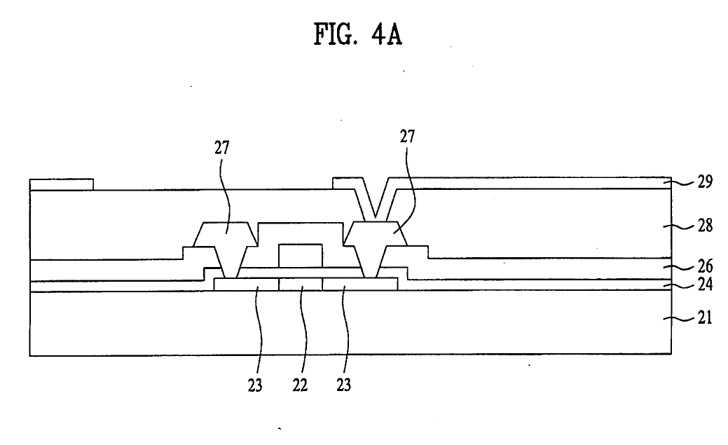

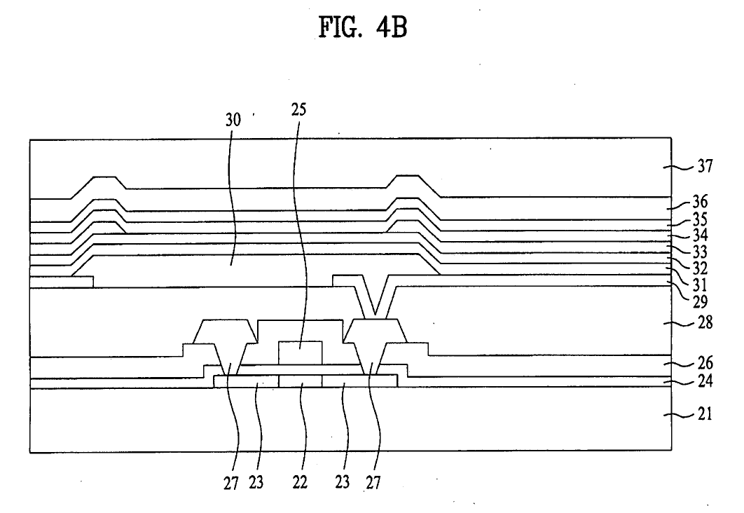

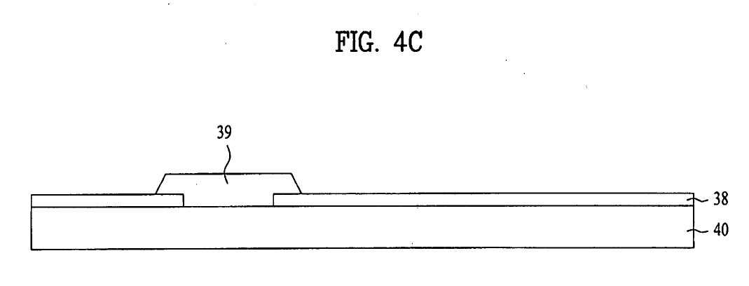

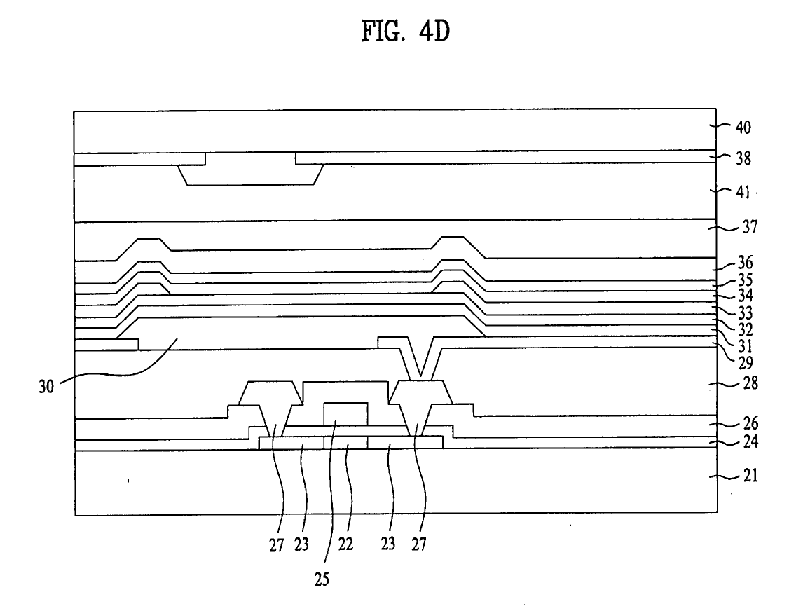

FIGS. 4A to 4D are sectional views illustrating a process for manufacturing an organic electro-luminescent display according to a second embodiment of the present invention.

The second embodiment of the present invention discloses a process for manufacturing a top emission type organic EL display.

Referring first to FIG. 4A, the semiconductor layer 22 made of, for example, polysilicon, is formed over the glass substrate 21. The semiconductor layer 22 is then patterned such that the semiconductor layer 22 remains only in a region where a thin film transistor is to be formed.

Thereafter, the gate insulating film 24 and the conductive film for formation of a gate electrode are sequentially formed over the entire surface of the resulting structure. The conductive film is then patterned to form the gate electrode 25.

Using the gate electrode 25 as a mask, impurity ions such as phosphorous (P) ions or boron (B) ions are then implanted into the semiconductor layer 22 which is, in turn, subjected to a heat treatment to form the source and drain regions 23 of the thin film transistor.

Next, the interlayer insulating film 26 is formed over the entire surface of the resulting structure. Subsequently, the interlayer insulating film 26 and gate insulating film 24 are selectively removed such that the source and drain regions 23 of the thin film transistor are exposed.

The electrode lines 27 are then formed on the exposed source and drain regions 23 such that the electrode lines 27 are electrically connected to the source and drain regions 23, respectively.

Subsequently, the flattening insulating film 28 is formed over the entire surface of the resulting structure and selectively removed such that the specific electrode line 27 connected to the drain region is exposed.

Then, the anode 29 is formed on the exposed electrode line 27 such that the anode 29 is electrically connected to the electrode line 27.

Here, the anode 29 is made of a transparent conductive material having a high work function, such as ITO, IZO, etc.

Thereafter, as shown in FIG. 4B, the insulating film 30 is formed between neighboring anodes 29.

Next, the hole injection layer 31, the hole transfer layer 32, the light-emitting layer 33, the electron transfer layer 34, the electron implantation layer 35, the cathode 36, and a protective film 37 are sequentially deposited over the entire surface of the resulting structure.

Here, the cathode 36 is made of a conductive material having a low work function, such as aluminum, etc. Alternatively, the cathode 36 is made of Ag, Ca, Mg or their alloy, or multiple films using them.

Then, as shown in FIG. 4C, the R, G, and B color filter layer 38 is formed on a corresponding pixel region of the protective cap 40 which is made of a transparent glass substrate or film-type substrate.

A black matrix layer 39 is formed between the color filter layer 38 and other neighboring color filter layers.

Thereafter, as shown in FIG. 4D, an adhesive 41 or sealant is formed over the protective film 37. If a protective film 40, formed with the color filter layer 38, is attached to the adhesive 41 or sealant, the manufacture of the organic EL display is completed.

Here, although not shown, a power supply line for applying a voltage to the thin-film transistor is formed such that a common power supply line is electrically connected to the thin-film transistors of neighboring pixel regions.

Also, the cathode 36 is a common electrode and can be grounded.

The above described organic EL display, which is manufactured by use of a white light emitting material, is driven in a digital manner.

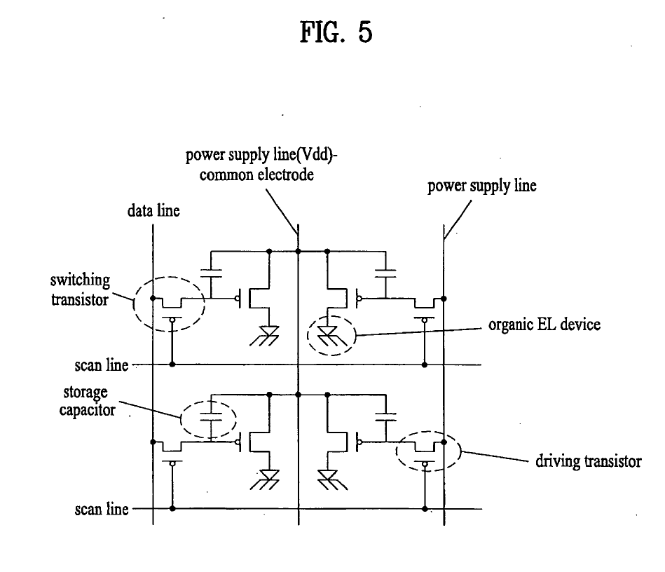

As shown in FIG. 5, differently from the prior art, the-present invention has a feature in that a Vdd line as a power supply line is connected to Red, Green, and Blue pixels together, so as to be used commonly by all the pixels.

In the present invention, organic EL devices formed at the respective pixels have approximately the same property as one another because of the use of a white light emitting device.

Accordingly, the present invention allows neighboring pixels to use a single power supply line in common, rather than using a separate power supply line individually.

A driving circuit of the present invention is accordingly designed such that neighboring pixels use a common power supply line, rather than using their individual power supply lines.

As compared to a conventional organic EL display that requires an individual power supply source and thus, has a great number of parts and a complicated circuit, the organic EL display of the preset invention can reduce the number of parts equal to at least one-third of that of the conventional organic EL display and achieve a simplified circuit configuration.

As apparent from the above description, the organic electro-luminescent (EL) display according to the present invention has the following effects.

Firstly, through the employment of a digital driving, the organic EL display of the present invention can improve the uniformity of image quality.

This is because organic EL devices formed at pixels operate in a linear region and thus, have no problem of irregular brightness that has been conventionally caused due to a difference in characteristics of organic EL devices.

Secondly, as a result of using a common single power supply line for R, G, and B pixels, the present invention can achieve a considerable reduction in the number of externally mounted elements, resulting in an outstanding improvement of price competitiveness and element mounting competitiveness.

Moreover, using the common power supply line for neighboring pixels has the effect of improving greatly the opening rate of pixels as well as the quality and lifespan of products. Consequently, the organic EL display of the present invention can achieve a high resolution.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An organic electro-luminescent display comprising:
an electro-luminescent device including at least one of emitting layers for emitting white light; and
a driving part for driving the electro-luminescent device,
wherein the electro-luminescent device is operated by digital driving.

2. The organic electro-luminescent display according to claim 1, wherein the driving part comprises:
a driving transistor for driving the organic electro-luminescent device; and
a common power supply line for applying a voltage to the driving transistor,
wherein the common power supply line is electrically connected to the driving transistors of neighboring ones of the pixel regions.

3. The organic electro-luminescent display according to claim 2, wherein a voltage applied to the driving transistor is equal to or lower than 30 V.

4. The organic electro-luminescent display according to claim 1, wherein the electro-luminescent device includes at least one of a red emitting layer containing a phosphorescent material, blue emitting layer containing a phosphorescent material and green emitting layer containing a phosphorescent material.

5. The organic electro-luminescent display according to claim 1, wherein the electro-luminescent device includes at least one of a red emitting layer containing a phosphorescent material, blue emitting layer containing a fluorescent material and green emitting layer containing a phosphorescent material.

6. The organic electro-luminescent display according to claim 1, wherein the electro-luminescent device includes at least one of a red emitting layer containing a phosphorescent material, blue emitting layer containing a fluorescent material and green emitting layer containing a fluorescent material.

7. An organic electro-luminescent display comprising an organic electro-luminescent device, a driving transistor, and a switching transistor, which are provided at each one of a plurality of pixel regions, further comprising:
a data line for applying a data signal to the switching transistor;
a scan line for applying a scan signal to the switching transistor; and
a common power supply line electrically connected to the driving transistors of neighboring ones of the pixel regions for applying a voltage to the driving transistors.

8. The organic electro-luminescent display according to claim 7, wherein the organic electro-luminescent device comprises:
a first electrode electrically connected to the driving transistor;
an organic electro-luminescent layer formed over the first electrode for emitting white light; and
a second electrode formed over the organic electro-luminescent layer.

9. The organic electro-luminescent display according to claim 8, wherein a color filter layer is formed on any one of a lower surface of the first electrode and an upper surface of the second electrode.

10. The organic electro-luminescent display according to claim 8, wherein the second electrode is grounded.

11. The organic electro-luminescent display according to claim 7, wherein the organic electro-luminescent device is operated by digital driving.

12. An organic electro-luminescent display comprising:
a transparent substrate having a plurality of pixel regions;
first and second transistors formed at each pixel region of the transparent substrate;
a first electrode formed at each pixel region and electrically connected to the first transistor;
an organic electro-luminescent layer formed over the first electrode for emitting white light;
a second electrode formed over the organic electro-luminescent layer;
a data line electrically connected to the second transistor for applying a data signal to the second transistor;
a scan line electrically connected to the second transistor for applying a scan signal to the second transistor; and
a common power supply line electrically connected to the first transistors of neighboring ones of the pixel regions for applying a voltage to the first transistors.

13. The organic electro-luminescent display according to claim 12, wherein a color filter layer is formed on at least any one of a lower surface of the first electrode and an upper surface of the second electrode.

14. The organic electro-luminescent display according to claim 12, wherein the second electrode is grounded.

15. The organic electro-luminescent display according to claim 12, wherein the organic electro-luminescent layer is formed by sequentially depositing at least one of both a hole injection layer and a hole transfer layer, a white light emitting layer, and at least one of both an electron transfer layer and an electron implantation layer over the first electrode.

16. The organic electro-luminescent display according to claim 12, wherein the organic electro-luminescent display is operated by digital driving.

17. An organic electro-luminescent display comprising:
a transparent substrate having a plurality of pixel regions;
a thin-film transistor formed at each pixel region in a non-light-emitting region of the pixel region;
a color filter layer formed at each pixel region in a light-emitting region of the pixel region;
an anode formed over the color filter layer and electrically connected to the thin film transistor;
an organic electro-luminescent layer formed over the anode for emitting white light;
a cathode formed over the organic electro-luminescent layer; and
a common power supply line electrically connected to the thin-film transistors of neighboring ones of the pixel regions for applying a voltage to the thin-film transistors.

18. An organic electro-luminescent display comprising:
a transparent substrate having a plurality of pixel regions;
a thin-film transistor formed at each pixel region in a non-light-emitting region of the pixel region;
an anode formed at each pixel region in a light-emitting region and electrically connected to the thin-film transistor;
an organic electro-luminescent layer formed over the anode for emitting white light; a cathode formed over the organic electro-luminescent layer;
a protective film formed over the cathode;
a color filter layer formed over the protective film;
a protective cap formed over the color filter layer; and
a common power supply line electrically connected to the thin-film transistors of neighboring ones of the pixel regions for applying a voltage to the thin-film transistors.

19. The organic electro-luminescent display according to claim 18, wherein the color filter layer is formed at each pixel region.

20. The organic electro-luminescent display according to claim 18, wherein a black matrix layer is formed between the color filter layer and other neighboring color filter layers.
